(19) United States
(12) Patent Application Publication
(10) Pub. No.: US 2025/0317321 A1
(43) Pub. Date: Oct. 9, 2025

(54) SYSTEM FOR MANAGING MOTOR-VEHICLE BATTERY CELLS, WITH INDEPENDENT POWER SUPPLY AND ETHERNET COMMUNICATION

(71) Applicant: Schaeffler Technologies AG & Co. KG, Herzogenaurach (DE)

(72) Inventors: Nathalie COMBET, Toulouse (FR); Thierry BAVOIS, Toulouse (FR)

(21) Appl. No.: 19/083,707

(22) Filed: Mar. 19, 2025

(30) Foreign Application Priority Data
Apr. 8, 2024 (FR) 2403583

(51) Int. Cl. H04L 12/40; H04L 41/0659

(52) U.S. Cl. CPC H04L 12/40032; H04L 12/40045; H04L 41/0659; H04L 2012/40273

(57) ABSTRACT

The invention relates to a system for managing cells (11) of a motor-vehicle battery, comprising a zone controller (1a) and at least two management boards (1b) connected by an Ethernet connection (2), wherein:
a. the zone controller (1a) comprises a DC power supply (1a3), designed to provide power on a pair of twisted conductors via the Ethernet connection (2) between the zone controller (1a) and the management boards (1b),
b. each management board (1b) comprising:
i. a data-processing stage comprising an Ethernet interface (1b20) connected to the Ethernet connection (2) and to the at least two managers (1b22) each designed to monitor at least one cell (11) of the battery,
ii. a power-supplying stage connected to the Ethernet connection (2) so as to provide power to each cell manager (1b22) and to the Ethernet interface (1b20) of the management board (1b) from the power provided by the DC power supply (1a3).

### TECHNICAL FIELD

The technical field of the invention is battery management, and more particularly battery management based on cell sensor circuits.

### PRIOR ART

A battery generally comprises a certain number of battery cells, for example 24 battery cells.

In order to monitor such batteries, a cell management system (CMS) is used. The CMS comprises at least one cell sensor circuit (CSC) tasked with monitoring at least one cell 11 of the battery 10. [FIG. 1] illustrates such a system.

By cell monitoring, what is meant is determining the voltage across the terminals of each cell. A plurality of CSCs are required to monitor all the cells of a battery.

These CSCs are connected in a daisy chain, i.e. via isolated point-to-point communication busses (isolation by capacitive coupling or transformers). One of the CSCs interfaces with an external microcontroller allowing communication with the rest of the vehicle. The CSC connected to the external microcontroller acts as the master controller insofar as the data of the other CSCs passes through it before reaching the external microcontroller.

Each CSC is powered directly by the monitored battery cells. Since the cells of a battery are connected in series, failure of one cell causes all the cells to fail. If one of the cells monitored by the CSC fails, the corresponding CSC is no longer supplied with power. Itis then not possible to determine which battery cell has failed.

In addition, the unpowered CSC can no longer act as a relay for information determined by the other CSCs placed downstream with respect to the connection to the master controller. Access to every CSC starting from the failed CSC is thus lost.

It will be noted that, in certain cases, provision is made for a backup master controller, placed last in the daisy chain of CSCs with respect to the master controller, this allowing the direction of the daisy chain to be reversed and access to be regained to the CSCs that can no longer be accessed via the master controller. Even in this case, it is still not possible to access the CSC normally powered by the group of cells comprising the failed cell. In addition, the presence of such a backup master controller increases the cost of a battery management system.

Such a battery management system obviously has a certain number of problems.

A first problem is related to the fact that failure of the power supply of one CSC prevents all the monitored cells from being monitored.

A second problem is related to the difficulty in determining which battery cell has failed in the event of failure of the power supply of a CSC. Since the voltage and current measurements of the various cells are no longer available, it is not possible to determine the one or more failed cells to replace. It is thus necessary to replace all the cells or to test them one by one. In both cases, repair is not cost effective.

A third problem is related to the increase in the complexity of a battery management system equipped with a backup controller making it possible to reverse the direction of interrogation of the daisy chain of CSCs.

A fourth problem is related to the non-negligible power consumption of the CSCs, contributing to discharge of the battery.

A fifth problem is related to the fact that communication of daisy-chain type is not standardized and has become a brake on the interoperability of solutions.

The aim of the present invention is to address these various technical problems.

### SUMMARY OF THE INVENTION

The invention relates to a system for managing cells of a motor-vehicle traction battery, comprising a zone controller and at least two management boards, each management board being designed to monitor at least one cell of the traction battery through voltage measurements, wherein:
a. the zone controller is connected to the management boards via an Ethernet connection,
b. the zone controller comprises a microcontroller, an Ethernet interface and a DC power supply, the microcontroller being designed to control the Ethernet interface and the DC power supply,
c. the DC power supply being designed to power the Ethernet interface and the microcontroller of the zone controller,
d. the DC power supply also being designed to provide power on a pair of twisted conductors via the Ethernet connection between the zone controller and the management boards,
e. each management board comprising a data-processing stage and a power-supplying stage, the data-processing stage comprising an Ethernet interface connected to the Ethernet connection and to at least two cell managers each designed to monitor at least one cell of the battery, the power-supplying stage being connected to the Ethernet connection so as to provide power to each cell manager and to the Ethernet interface of the management board.

The power-supplying stage may comprise a DC-AC converter an input of which is connected to the Ethernet connection via a power line, and, for each cell manager of the management board, an isolating means connected in series with an AC-DC converter.

The isolating means may be of inductive type, and in particular an isolation transformer.

An isolating means may be placed between each Ethernet interface and the Ethernet connection.

The isolating means may be of capacitive type, and for example an isolation capacitor.

The data-processing stage of a management board may comprise a data buffer connected between the Ethernet interface and the cell managers.

In a management board, the cell managers may form a daisy chain in which the first cell manager is connected by a first point-to-point connection to the data buffer and by another point-to-point connection to another cell manager, the other cell managers each being connected to their nearest neighbor by a second point-to-point connection, so that the data transmitted by one cell manager passes from one to another to the data buffer.

The first point-to-point connection may be an SPI connection, the second point-to-point connection being a galvanically isolated SPI connection.

In a management board, the cell managers may each be connected to the data buffer via a data bus.

The data bus may be of SPI type, at least one of the cell managers being isolated from the data bus via an isolation capacitor.

### BRIEF DESCRIPTION OF DRAWINGS

Other aims, features and advantages of the invention will become apparent on reading the following description, which is given merely by way of non-limiting example and with reference to the appended drawings, in which:

FIG. 1 illustrates a CMS according to the prior art,

FIG 2 illustrates the main elements of a CMS according to the invention,

FIG 3 illustrates the main elements of a power-supplying stage of a management board included in a CMS according to the invention,

FIG. 4 illustrates the main elements of a data-processing stage of a management board included in a first embodiment of a CMS according to the invention, and

FIG. 5 illustrates the main elements of a data-processing stage of a management board according to a second embodiment of a CMS according to the invention.

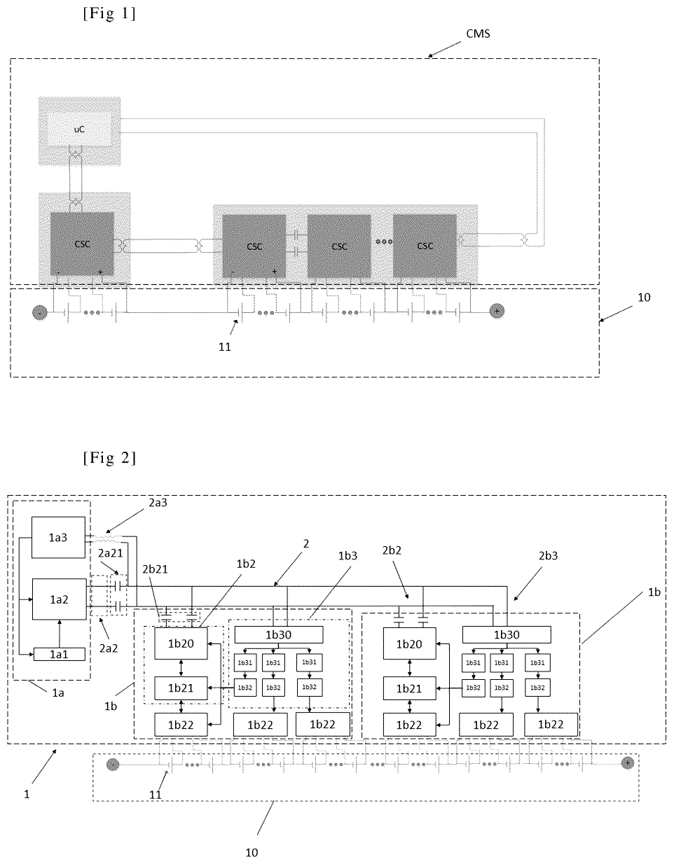

### DETAILED DESCRIPTION

The CMS according to the invention is referenced 1 in [FIG. 2]. It comprises a zone controller 1a connected to at least two management boards 1b by an Ethernet connection referenced 2. The Ethernet connection is in particular a connection according to the standard IEEE 802.3cg, to support the communication protocol 10BASE-T1S, using a pair of twisted conductors.

The zone controller 1a is placed generally centrally in the vehicle, or at the very least close to the other computers or electronic control units of the vehicle. Specifically, the zone controller communicates with the other computers or electronic control units of the vehicle via an Ethernet connection.

By contrast, the management boards 1b are placed on the battery 10, as close as possible to the monitored cells 11, for reasons of cost and of range of the connections to the terminals of the cells.

The zone controller 1a comprises a microcontroller 1a1, an Ethernet interface 1a2 and a DC power supply 1a3. By Ethernet interface, what is meant is a level 1 hardware interface in the OSI model (OSI standing for Open System Interconnection).

Within the zone controller 1a, the microcontroller 1a1 is connected by a data line to the Ethernet interface 1a2, in particular a line of xMII type (xMII standing for Media Independent Interface) or SPI type (SPI standing for Serial Peripheral Interface).

The Ethernet interface 1a2 is connected to the Ethernet connection 2 by a data line 2a2 via an isolating means 2a21. The isolating means 2a21 is in particular of capacitive type, for example one isolation capacitor for each conductor of the Ethernet connection 2.

The DC power supply 1a3 supplies power to the Ethernet interface 1a2 and the microcontroller 1a1.

The DC power supply 1a3 is moreover connected to the Ethernet connection 2 by a power line 2a3 in order to provide power according to the PoDL standard (PoDL standing for Power Over Data Lines, standard IEEE 802.3bu) via the Ethernet connection 2.

Each management board 1b comprises a data line 2b2 and a power line 2b3 connected to the Ethernet connection, each taking the form of a pair of conductors.

It will be recalled that a PoDL power supply supplies power on a pair of twisted connectors, the supply of power being superposed on the voltage variations generated by the transmission of data.

Each management board 1b comprises a data-processing stage 1b2 and a power-supplying stage 1b3.

The data-processing stage comprises an Ethernet interface 1b20 connected to the Ethernet connection 2 via an isolating means 2b21. The isolating means 2b21 is in particular of capacitive type, for example one isolation capacitor for each conductor of the Ethernet connection 2.

The Ethernet interface 1b20 is also connected to a data buffer 1b21 which is itself connected to at least one cell manager 1b22 by a serial communication link of SPI type. In one particular embodiment, the data buffer 1b21 is connected to the Ethernet interface 1b20 by an xMII link. The role of the data buffer 1b21 is to manage conversion of the data exchanged between the at least one cell manager 1b22 and the Ethernet interface 1b20, and to manage any synchronicity.

Each cell manager 1b22 manages a plurality of battery cells 11.

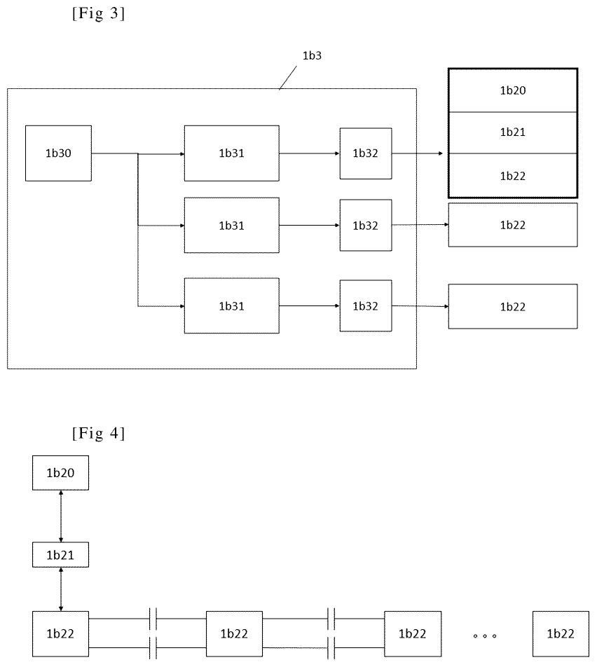

The power-supplying stage 1b3 connected to each manager 1b22 comprises a DC-AC converter 1b30, an isolating means 1b31 and an AC-DC converter 1b32. [FIG. 3] illustrates only the power-supplying stage of a management board.

Although expensive, providing each cell manager 1b22 with an AC-DC converter 1b32 is particularly advantageous in that it allows the necessary power to be supplied taking into account, for each AC-DC converter 1b32, a different reference voltage indexed to the voltage of the monitored cells. Specifically, depending on their state of charge, the groups of cells forming in the prior art the power source of the CSCs have voltages varying between a few tens of volts and a few hundred volts.

In a first embodiment of a data-processing stage, illustrated by [FIG. 4], a first cell manager is connected to the data buffer 1b21 by a first SPI connection. The first cell manager is then connected to a second cell manager by a second ISO SPI connection. By ISO SPI connection, what is meant is an SPI connection comprising a galvanic isolation. Each of the other cell managers is connected to a single other cell manager by an ISO SPI connection, so as to form a daisy chain.

Such an embodiment remains similar to the prior art, while simplifying the data lines through use of SPI and ISO SPI connections and solving the problems with supplying power to the cell managers 1b22 by supplying them power from the data line instead of from the battery cells.

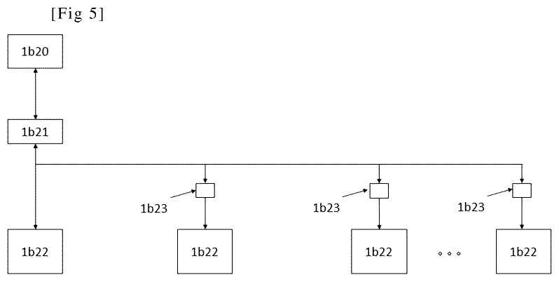

In a second embodiment of a data-processing stage, illustrated by [FIG. 5], an SPI data bus connects each of the cell managers 1b22 to the data buffer 1b21. Preferably, each of the cell managers 1b22 is equipped with a galvanic isolation 1b23 at its connection to the SPI data bus. The galvanic isolation of the first cell manager may be omitted because it is supplied with power by the same power supply as the data buffer 1b21 and the Ethernet interface 1b20. Any defect affecting the Ethernet interface and the data buffer will also affect its ability to communicate.

The galvanic isolation 1b23 of the cell managers is achieved via a digital circuit, in particular of optical, capacitive, radio-frequency or inductive type.

This embodiment has the advantage of improving the robustness of the management board by making communication between the data buffer and the cell managers independent of the operation of each cell manager. In the event of malfunction of one of the cell managers, the other cell managers remain accessible.

1. A system for managing cells (11) of a motor-vehicle traction battery, comprising a zone controller (1a) and at least two management boards (1b), each management board (1b) being designed to monitor at least one cell (11) of the traction battery through voltage measurements, wherein:
a. the zone controller (1a) is connected to the management boards (1b) via an Ethernet connection (2),
b. the zone controller (1a) comprises a microcontroller (1a1), an Ethernet interface (1a2) and a DC power supply (1a3), the microcontroller (1a1) being designed to control the Ethernet interface (1a2) and the DC power supply (1a3),
c. the DC power supply (1a3) being designed to power the Ethernet interface (1a2) and the microcontroller (1a1) of the zone controller (1a),
d. the DC power supply (1a3) also being designed to provide power on a pair of twisted conductors via the Ethernet connection (2) between the zone controller (1a) and the management boards (1b),
e. each management board (1b) comprising a data-processing stage and a power-supplying stage, the data-processing stage comprising an Ethernet interface (1b20) connected to the Ethernet connection (2) and to at least two cell managers (1b22) each designed to monitor at least one cell (11) of the battery, the power-supplying stage being connected to the Ethernet connection (2) so as to provide power to each cell manager (1b22) and to the Ethernet interface (1b20) of the management board (1b) from the power provided by the DC power supply (1a3).

2. The management system as claimed in claim 1, wherein the power-supplying stage comprises a DC-AC converter (1b30) an input of which is connected to the Ethernet connection (2) via a power line, and, for each cell manager (1b22) of the management board, an isolating means (1b31) connected in series with an AC-DC converter (1b32).

3. The management system as claimed in claim 2, wherein the isolating means (1b31) is of inductive type, and in particular an isolation transformer.

4. The management system as claimed in claim 1, wherein an isolating means is placed between each Ethernet interface (1a2, 1b20) and the Ethernet connection (2).

5. The management system as claimed in claim 4, wherein the isolating means is of capacitive type, and for example an isolation capacitor.

6. The management system as claimed in claim 1, wherein the data-processing stage comprises a data buffer (1b21) connected between the Ethernet interface (1b20) and the cell managers (1b22).

7. The management system as claimed in claim 6, wherein, in a management board (1b), the cell managers (1b22) form a daisy chain in which the first cell manager (1b22) is connected by a first point-to-point connection to the data buffer (1b21) and by another point-to-point connection to another cell manager (1b22), the other cell managers (1b22) each being connected to their nearest neighbor by a second point-to-point connection, so that the data transmitted by one cell manager (1b22) passes from one to another to the data buffer (1b21).

8. The management system as claimed in claim 7, wherein the first point-to-point connection is an SPI connection, the second point-to-point connection being a galvanically isolated SPI connection.

9. The management system as claimed in claim 6, wherein, in a management board (1b), the cell managers (1b22) are each connected to the data buffer (1b21) via a data bus.

10. The management system as claimed in claim 9, wherein the data bus is of SPI type, at least one of the cell managers (1b22) being isolated from the data bus via an isolation capacitor (1b23).
